(19) United States
(12) Patent Application Publication
(10) Pub. No.: US 2026/0372067 A1
(43) Pub. Date: Nov. 19, 2026

(54) INTEGRATED CIRCUIT E-FUSE DEVICE

(71) Applicant: Microchip Technology Inc., Chandler, AZ (US)

(72) Inventor: Yaojian Leng, Vancouver, WA (US)

(73) Assignee: Microchip Technology Inc., Chandler, AZ (US)

(21) Appl. No.: 19/257,860

(22) Filed: Jul. 2, 2025

Related U.S. Application Data
(60) Provisional application No. 63/805,434, filed on May 14, 2025.

(51) Int. Cl. H10W 20/49

(52) U.S. Cl. CPC H10W 20/493

(57) ABSTRACT

An e-fuse device may include a lower e-fuse terminal, an upper e-fuse terminal, and a cup-shaped e-fuse element connected between the lower e-fuse terminal and upper e-fuse terminal, the cup-shaped e-fuse element including an e-fuse element base and an e-fuse element sidewall extending upwardly from the e-fuse element base. The e-fuse device may include a shock absorber formed in a cavity defined by the cup-shaped e-fuse element.

### RELATED APPLICATION

This application claims priority to commonly owned U.S. Provisional Patent Application No. 63/805,434 filed May 14, 2025, the entire contents of which are hereby incorporated by reference for all purposes.

### TECHNICAL FIELD

The present disclosure relates to e-fuse devices, in particular to an integrated circuit (IC) e-fuse device and methods of forming an IC e-fuse device.

### BACKGROUND

A fuse is a resistive link, which can be permanently programmed between a conductive state and a highly resistive state. An e-fuse uses electric current (as opposed to laser) to cause the change of resistance (programming). E-fuses are useful in a wide range of applications, for example (a) for protection from ESD (Electrostatic Discharge) during manufacture and handling, (b) for removing or replacing a defective device from a circuit, (c) for programming one-time programmable memory, for example ROM (Read Only Memory), OTP (One Time Programmable memory), or PROM (Programable Read Only Memory), without limitation, (d) for electronic digital trim of passive components (e.g., resistors, capacitors, or inductors), or (e) to provide chip security by preventing unauthorized access.

In the integrated circuit industry, the predominant type of e-fuse is the salicide poly e-fuse, in which a silicide region formed on the polysilicon forms a low resistance path before programming, and is purposefully destroyed by high current during programming, which changes the fuse to a high-resistance state. A conventional poly silicide fuse element may be programmed through electro migration, wherein a large current, for example 10 mA, is driven through the fuse element, which ruptures the fuse element and thereby switches the fuse from a low resistance state to a high resistance state.

However, the poly e-fuse is not available in high-k/dielectric and metal gate transistor technology. In contrast to poly e-fuse, a metal fuse is generally preferred due to its low melting point and ease of programming using electromigration. Thus, in some advanced CMOS designs, interconnect metal or via is used as a metal fuse without introducing dedicated e-fuse metal, through thermally accelerated metal electromigration. However, this process is typically very complicated and requires specialized programming because only some parts of the circuit (components associated with the e-fuse) are programmed by electromigration, while other parts of the circuit (e.g., normal CMOS components) must be protected from electromigration.

In addition, the burning/rupturing of a conventional e-fuse element (to program the fuse) often cause collateral damage to neighboring structures, which may significantly limit the minimum size and density of conventional e-fuses, and may also affect the relevant device reliability.

There is a need for improved metal e-fuses for integrated circuits, for example e-fuses that can be fabricated at relatively low cost, reliably, and with high density. Further, there is a need or advantage (e.g., cost and time advantage) to reduce or minimize the number of mask layers needed to construct integrated e-fuses.

### SUMMARY

Examples of the present disclosure provide an integrated circuit e-fuse device including a shock absorber to reduce collateral damage or other effects on neighboring structures resulting from programming (i.e., burning/destroying) the e-fuse element. For example, the shock absorber may dampen the programming shock wave, which may allow increased e-fuse density and device reliability.

In some examples, the e-fuse device includes a cup-shaped e-fuse element and a shock absorber formed in an opening defined by the cup-shaped e-fuse element. The cup-shaped e-fuse element may define a vertical e-fuse, i.e., wherein a programming current burns/destroys a thin vertical sidewall of the cup-shaped e-fuse element. In some examples, the e-fuse device includes a cup-shaped e-fuse element may be formed from NiCr, tin, lead, silver, copper, zinc, aluminum, or an alloy of lead and tin.

In some examples, the shock absorber comprises a dielectric material. In some examples, the shock absorber comprises a porous dielectric material, for example porous OSG (Organo-silicate glass) or spin-on glass, such as HSQ (Hydrogen Silsesquioxane).

In some examples, the e-fuse device is cost effective, and may be constructed concurrently with interconnect structures, and may add no photomask processes to the background device fabrication process.

In some examples, the e-fuse device may be programmed using a low and adjustable programming voltage. In some examples, the e-fuse material different from normal contact or via, may be optimized or selected for e-fuse functionality, and may be designed for low voltage programing. In some examples, the programing voltage may be adjusted by tuning the ratio between the e-fuse film deposition thickness and the dielectric shock absorber thickness.

In some examples, the e-fuse device may be constructed between Mx and Mx+1, which may represent two metal interconnect layers or alternatively a silicided poly layer/structure and a first metal layer (metal-1 or M1).

One aspect provides an e-fuse device, comprising a lower e-fuse terminal, an upper e-fuse terminal, and a cup-shaped e-fuse element connected between the lower e-fuse terminal and upper e-fuse terminal, the cup-shaped e-fuse element including an e-fuse element base and an e-fuse element sidewall extending upwardly from the e-fuse element base.

In some examples, the cup-shaped e-fuse element comprises nichrome (NiCr), tin, lead, silver, copper, zinc, aluminum, or an alloy of lead and tin.

In some examples, the e-fuse device includes a shock absorber formed in a cavity defined by the cup-shaped e-fuse element. For example, the shock absorber may be contained in a chamber defined between the cup-shaped e-fuse element and the upper e-fuse terminal.

In some examples, the shock absorber comprises a dielectric material, for example a porous dielectric material. In some examples, the shock absorber comprises organo-silicate glass (OSG), hydrogen silsesquioxane (HSQ), silicon oxide, or fluorosilicate glass (FSG).

In some examples, the e-fuse device includes a lower e-fuse terminal contact pad adjacent the upper e-fuse terminal, and a lower e-fuse terminal contact adjacent the cup-shaped e-fuse element and defining a conductive connection between the lower e-fuse terminal contact pad and the lower e-fuse terminal. In some examples, the lower e-fuse terminal contact pad and the upper e-fuse terminal are formed in the same metal interconnect layer.

Another aspect provides an IC device, including a lower metal layer, an upper metal layer, a via layer between the lower metal layer and upper metal layer, an e-fuse device, and an interconnect structure. The e-fuse device may include a lower e-fuse terminal formed in the lower metal layer, an upper e-fuse terminal formed in the upper metal layer, and a cup-shaped e-fuse element formed in the via layer and connected between the lower e-fuse terminal and the upper e-fuse terminal. The interconnect structure may be laterally offset from the e-fuse device, and may include a lower interconnect element formed in the lower metal layer, an upper interconnect element formed in the upper metal layer, and at least one via formed in the via layer, the at least one via conductively connected between the lower interconnect element and upper interconnect element.

In some examples, the e-fuse device comprises a shock absorber formed in a cavity defined by the cup-shaped e-fuse element.

In some examples, the shock absorber comprises a porous dielectric material.

In some examples, the e-fuse element is formed from a different metal than the at least one via.

In some examples, the e-fuse device includes a lower e-fuse terminal contact pad adjacent the upper e-fuse terminal, and a lower e-fuse terminal contact adjacent the cup-shaped e-fuse element and defining a conductive connection between the lower e-fuse terminal contact pad and the lower e-fuse terminal.

Another aspect provides a method of forming an e-fuse device, including forming a lower e-fuse terminal, forming a dielectric region over the lower e-fuse terminal, forming a tub opening in the dielectric region over the lower e-fuse terminal, forming a cup-shaped e-fuse element in the tub opening, and forming an upper e-fuse terminal over the cup-shaped e-fuse element, wherein the cup-shaped e-fuse element is conductively connected between the lower e-fuse terminal and upper e-fuse terminal.

In some examples, the method includes forming a shock absorber in a cavity defined by the cup-shaped e-fuse element.

In some examples, forming the shock absorber comprises depositing a porous dielectric material over the dielectric region and extending down into the cavity defined by the cup-shaped e-fuse element.

In some examples, the method includes forming, in the dielectric region, (a) the tub opening over the lower e-fuse terminal and (b) at least one via opening over the lower interconnect element; depositing a via metal layer over the dielectric region and extending down into the at least one via opening and into the tub opening; and removing the via metal layer from the tub opening prior to forming the cup-shaped e-fuse element in the tub opening.

In some examples, the method includes forming the lower e-fuse terminal and a lower interconnect element in a lower metal layer; forming the dielectric region over the lower metal layer; forming, in the dielectric region, (a) the tub opening over the lower e-fuse terminal and (b) at least one via opening over the lower interconnect element; depositing a via metal layer over the dielectric region and extending down into the at least one via opening and into the tub opening; performing an etch to remove the via metal layer from the tub opening; depositing an e-fuse element layer over the dielectric region and extending down into the tub opening to form a cup-shaped e-fuse element structure in the tub opening; depositing a shock absorber layer over the e-fuse element layer and extending down into a cavity defined by the cup-shaped e-fuse element structure in the tub opening; performing a planarization process to remove upper portions of the e-fuse element layer and shock absorber layer, wherein a remaining portion of the e-fuse element layer in the tub opening defines the cup-shaped e-fuse element, and wherein a remaining portion of the shock absorber layer in the tub opening defines a shock absorber; and forming the upper e-fuse terminal and an upper interconnect element in a lower metal layer, wherein the upper interconnect element is electrically connected to the lower interconnect element by the at least one via.

### BRIEF DESCRIPTION OF THE DRAWINGS

Example aspects of the present disclosure are described below in conjunction with the figures, in which:

FIG. 1 shows an example e-fuse device including a cup-shaped e-fuse element and a shock absorber formed in a cavity defined by the cup-shaped e-fuse element;

FIG. 2 shows an example IC device including the example e-fuse device shown in FIG. 1 and an example interconnect structure laterally spaced apart from the e-fuse device;

FIGS. 3A-3H illustrate an example process of forming the example IC device shown in FIG. 2;

FIG. 4 illustrates an example IC device including an e-fuse device formed between a silicided poly layer and a first metal interconnect layer (i.e., Metal-1 or M1 layer); and

FIG. 5 is a flowchart of an example method for forming an e-fuse device, e.g., the example e-fuse device shown in FIG. 1.

It should be understood that the reference number for any illustrated element that appears in multiple different figures has the same meaning across the multiple figures, and the mention or discussion herein of any illustrated element in the context of any particular figure also applies to each other figure, if any, in which that same illustrated element is shown.

### DETAILED DESCRIPTION

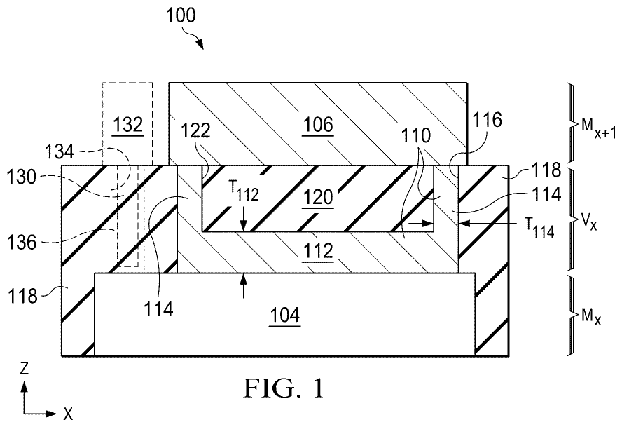

FIG. 1 shows an example e-fuse device 100 formed in an integrated circuit (IC) and including a lower e-fuse terminal 104, an upper e-fuse terminal 106, and a cup-shaped e-fuse element 110 connected between the lower e-fuse terminal 104 and upper e-fuse terminal 106. The cup-shaped e-fuse element 110 includes a laterally-extending e-fuse element base 112 and at least one vertically-extending e-fuse element sidewall 114 extending upwardly from the e-fuse element base 112 (assuming the orientation of the e-fuse device 100 shown in FIG. 1).

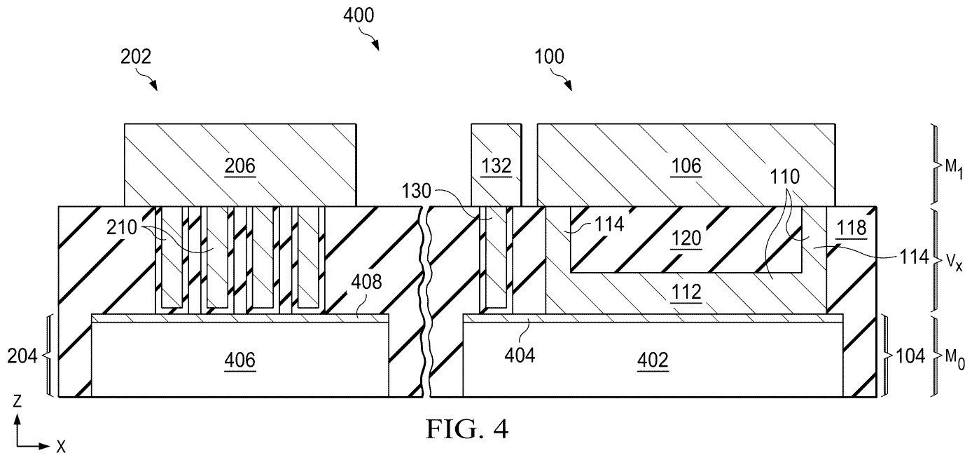

In some examples, the lower e-fuse terminal 104 is formed in a lower metal layer (Mₓ), the upper e-fuse terminal is formed in an upper metal layer (Mₓ₊₁), and the cup-shaped e-fuse element 110 is formed in a via layer (Vₓ) between the lower metal layer (Mₓ) and upper metal layer (Mₓ₊₁). In some examples, the lower metal layer Mₓ and upper metal layer Mₓ₊₁ may comprise respective metal interconnect layers at any height in a stacked IC structure, for example, M₁ and M₂ interconnect layers, M₂ and M₃ interconnect layers, or M₃ and M₄ interconnect layers, etc., formed from aluminum, copper or other suitable metal. In other examples, for example as shown in FIG. 4 discussed below, the upper metal layer Mₓ₊₁ may comprise a first metal interconnect layer (Mₓ₊₁=M₁ or “Metal-1”), and the lower metal layer (Mₓ=M₀) may comprise conductive structures formed below the Metal-1 layer, for example, silicided regions formed on respective transistor structures or other conductive structures formed below the Metal-1 layer. The e-fuse element 110 may be formed in a tub opening 116 formed in a dielectric region 118, e.g., comprising Silicon Oxide, PSG (Phosphosilicate glass), BPSG (Borophosphosilicate Glass), or any combination thereof.

Regarding the cup-shaped e-fuse element 110, the at least one vertically-extending e-fuse element sidewall 114 may include one or more sidewalls 114 defining a ring shape in a cross-section through a horizontal (x-y) plane. For example, the cup-shaped e-fuse element 110 may include four sidewalls 114 defining a rectangular shape in the horizontal plane, or may include a single sidewall 114 having a circular shape in the horizontal plane.

The e-fuse element sidewall 114 may have a small thickness (in the x-direction or y-direction) relative to a thickness (in the z-direction) of the e-fuse element base 112 due to the characteristics of step coverage of Physical Vapor Deposition (PVD) process. In some examples, the thickness T₁₁₄ of the fuse element sidewall 114 may be in the range of 50-500 Å, while the thickness T₁₁₂ of the e-fuse element base 112 may be in the range of 100 Å to 1000 Å.

In some examples, the cup-shaped e-fuse element 110 comprises nichrome (NiCr). In other examples, the cup-shaped e-fuse element 110 comprises tin, lead, silver, copper, zinc, aluminum, an alloy of lead and tin, or other suitable material.

As shown, the e-fuse device 100 may include a shock absorber 120 formed in a cavity 122 defined by the cup-shaped e-fuse element 110. For example, the shock absorber may be contained in a chamber defined between the cup-shaped e-fuse element 110 and the upper e-fuse terminal 106. The shock absorber 120 may function to reduce collateral damage or other effects on neighboring structures resulting from programming (i.e., burning/destroying) the e-fuse element 110. For example, the shock absorber 120 may dampen the programming shock wave, which may allow increased e-fuse density and device reliability.

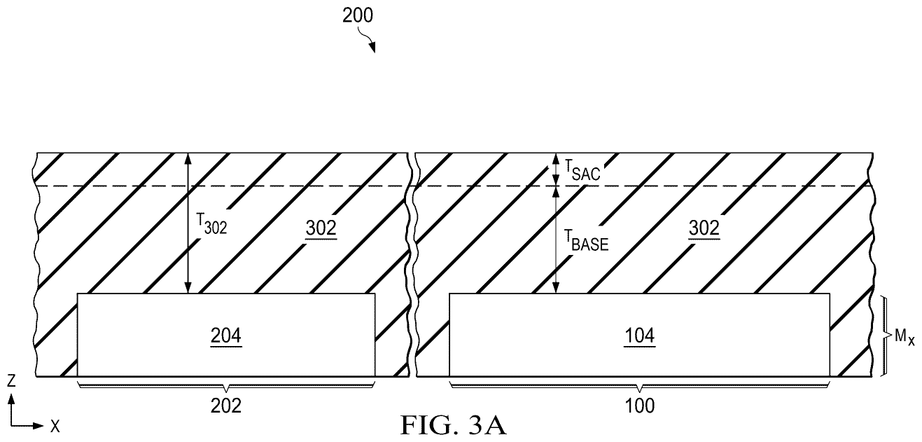

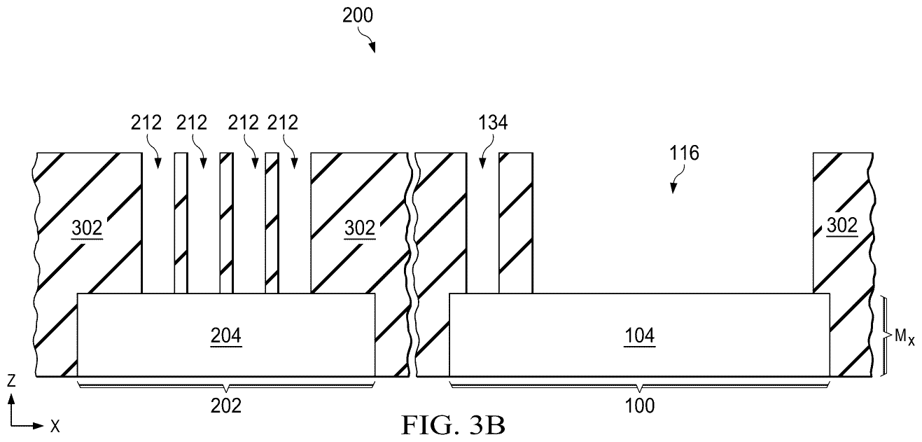

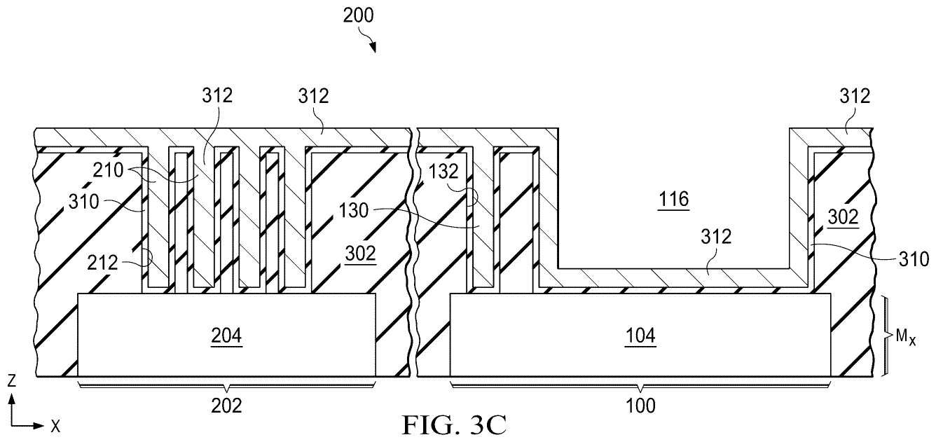

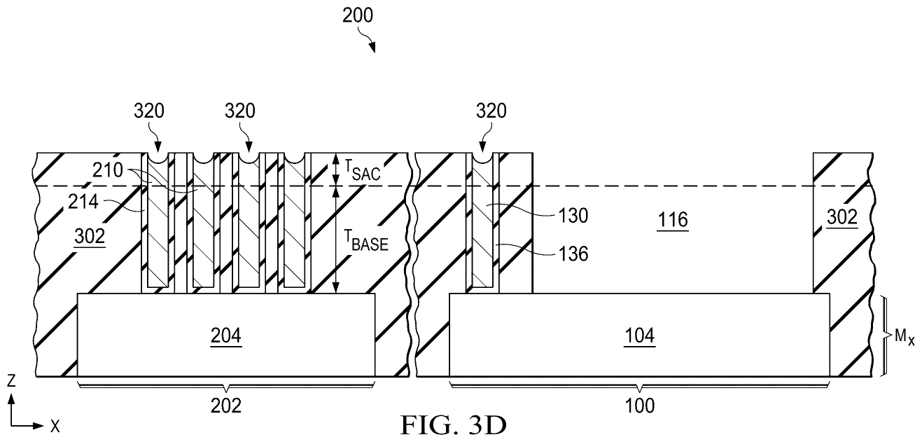

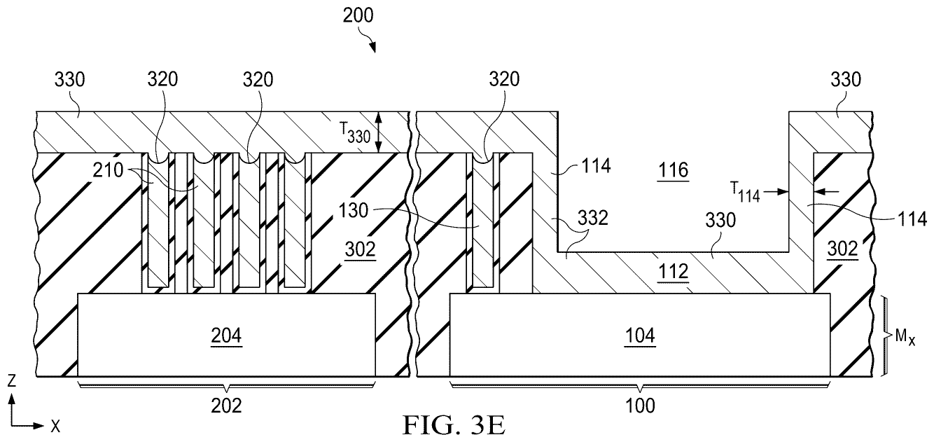

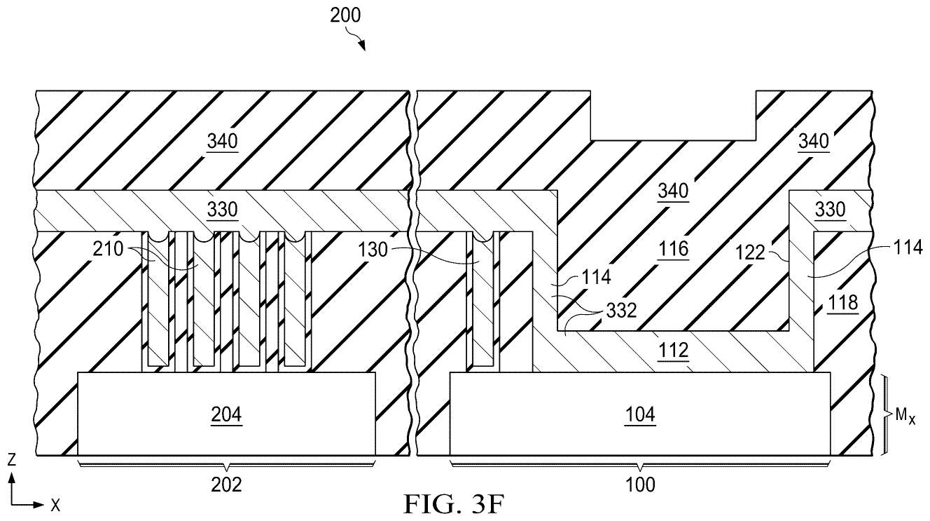

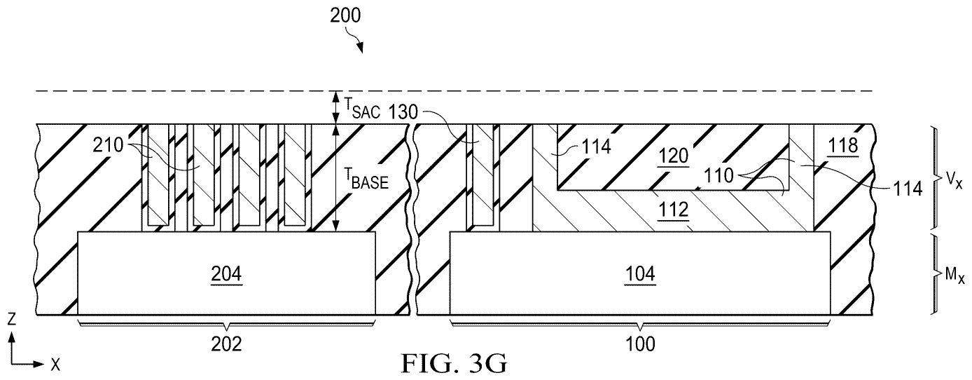

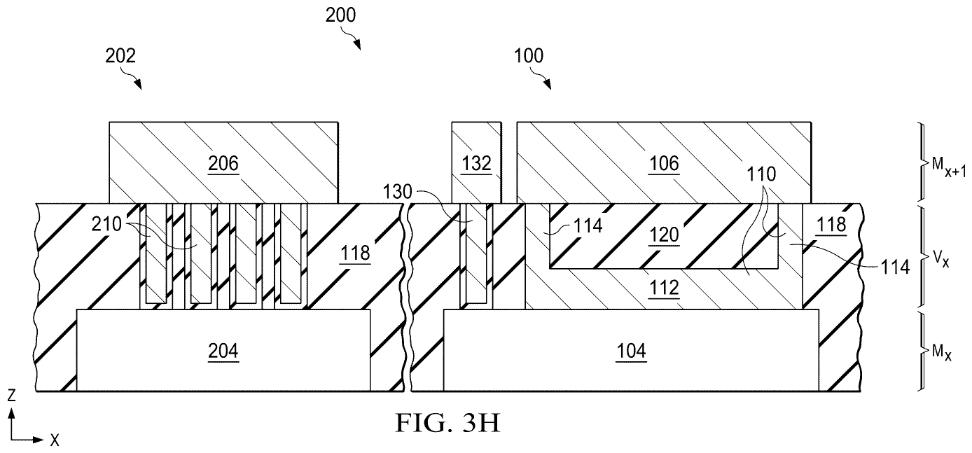

In some examples, the e-fuse device 100 may be programmed using a low and adjustable programming voltage. In some examples, the material of the shaped e-fuse element 110 may be different than typical contact or via metals, may be selected for desired or improved e-fuse functionality, and may be designed for low voltage programing. In some examples, the programing voltage may be adjusted by tuning the thickness T₁₁₄ of the e-fuse element sidewall 114, which may be defined by a thickness of a deposited e-fuse layer/film (thickness T₃₃₀ shown in FIG. 3E and discussed below) that forms the cup-shaped e-fuse element 110.

As shown, the e-fuse device 100 may also include a lower e-fuse terminal contact 130 formed in a via opening 134 (e.g., over a liner layer 136 comprising titanium nitride (TiN) or other suitable liner) laterally adjacent the cup-shaped e-fuse element 110 and electrically connected to the lower e-fuse terminal 104, and a lower e-fuse terminal contact pad 132 formed laterally adjacent the upper e-fuse terminal 106 and electrically connected to the lower e-fuse terminal 104 via the lower e-fuse terminal contact 130. The lower e-fuse terminal contact pad 132 may be formed in the upper metal layer (Mₓ₊₁), along with the upper e-fuse terminal 106 as discussed above.

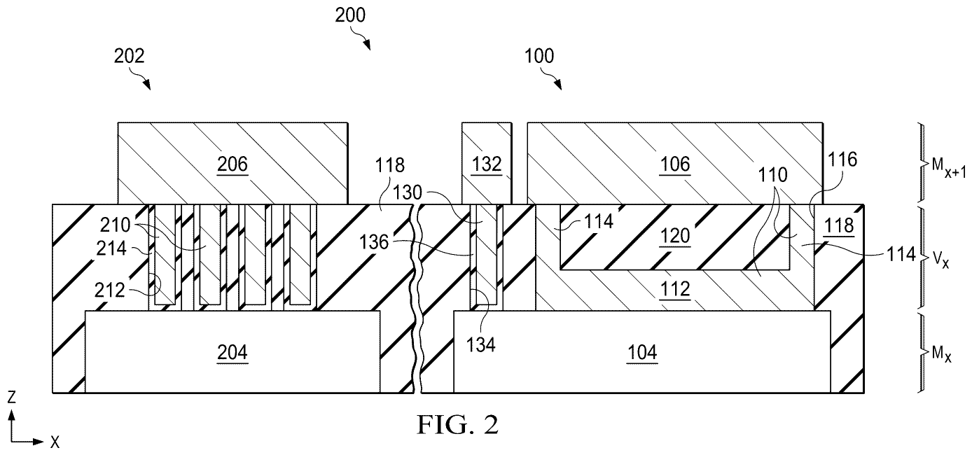

FIG. 2 shows an example IC device 200 including the example e-fuse device 100 shown in FIG. 1 and an example interconnect structure 202 formed laterally spaced apart from the e-fuse device 100. The example interconnect structure 202 may include a lower interconnect element 204 formed in the lower metal layer Mₓ, an upper interconnect element 206 formed in the upper metal layer Mₓ₊₁, and at least one via 210 formed in the via layer Vₓ and connected between the lower interconnect element 204 and upper interconnect element 206. Vias 210 may be formed in respective via openings 212 over a liner layer 214, e.g., comprising titanium nitride (TiN).

In this example, (a) the lower e-fuse terminal 104 of the e-fuse device 100 and the lower interconnect element 204 are formed (e.g., concurrently) in a lower metal layer (Mₓ). The upper e-fuse terminal 106 of the and (optional) lower e-fuse terminal contact pad 132 of the e-fuse device 100, and the upper interconnect element 206 of the interconnect structure 202 are formed (e.g., concurrently) in an upper metal layer (Mₓ₊₁). The cup-shaped e-fuse element 110, shock absorber 120, and (optional) lower e-fuse terminal contact 130 of the e-fuse device 100, and the via(s) 210 of the interconnect structure 202 are formed in a via layer (Vₓ) between the lower metal layer (Mₓ) and upper metal layer (Mₓ₊₁).

FIGS. 3A-3H illustrate an example process of forming the example IC device 200 shown in FIG. 2. As shown in FIG. 3A, the lower e-fuse terminal 104 and lower interconnect element 204 are formed in a lower metal layer Mₓ. A dielectric region 302 is then formed over the lower metal layer Mₓ. The dielectric region 302 is formed over the lower metal layer Mₓ (e.g., by PECVD) and planarized (e.g., by chemical mechanical planarization (CMP)) to a total thickness T₃₀₂ including (a) a base thickness T_{BASE} (e.g., in the range of 5000 Å to 10,000 Å) corresponding with the final thickness of the dielectric region 118 (i.e., the final structure shown in FIG. 3H) and (b) a sacrificial thickness T_{SAC} (e.g., in the range of 500 Å to 2000 Å (0.05-0.2 μm)) provided to account for the etched recesses 320 formed in the tops of metal contact structures 210 and 130 as discussed below with reference to FIG. 3D. In some examples, the base thickness T_{BASE} and sacrificial thickness T_{SAC} comprise respective portions of a continuous region of dielectric material, e.g., silicon dioxide (SiO₂). In other examples, the base thickness T_{BASE} comprises Silicon Oxide, PSG (Phosphosilicate glass), BPSG (Borophosphosilicate Glass), FSG (Fluorosilicate glass), OSG (Organosilicate glass), or a combination of them and the sacrificial thickness T_{SAC} comprises a second, different dielectric material (e.g., silicon oxide deposited over the first dielectric material.

As shown in FIG. 3B, via openings 212, via opening 134, and an e-fuse tub opening 116 are patterned and etched in the dielectric region 302, e.g., using known photolithography processes. In some examples, respective via openings 212 and via opening 134 may have a critical dimension (CD) (x-direction and y-direction) in the range of 0.1-0.5 μm, while the e-fuse gate tub opening 116 may have a dimension (x-direction and y-dimension) in the range of 1-10 μm.

As shown in FIG. 3C, a liner layer 310 (e.g., comprising titanium nitride (TiN)) may be deposited, followed by deposition of a conformal via metal 312 (e.g., tungsten film layer), e.g., by chemical vapor deposition (CVD), which conformal via metal 312 extends down into the via openings 212, the via opening 134, and the e-fuse tub opening 116. As shown, the conformal via metal 312 may fully fill the via openings 212 and via opening 134 and partially fill the e-fuse tub opening 116.

As shown in FIG. 3D, a via metal etch is performed to remove the via metal 312 from the e-fuse tub opening 116. The via metal etch may be a wet or dry (plasma) etch, and may be isotropic to fully remove the via metal 312 from the e-fuse tub opening 116. As shown, the etch removes the via metal 312 on top of the dielectric region 302, and may form a recess 320 in the remaining via metal 312 in each of the via openings 212 and via opening 134. In some examples, the recesses 230 do not extend below the sacrificial thickness T_{SAC} of the dielectric region 302.

As shown in FIG. 3E, an e-fuse element layer (e.g., film) 330 is deposited over the structure and extending down into the e-fuse tub opening 116 to define a cup-shaped e-fuse element structure 332 in the e-fuse tub opening 116. The cup-shaped e-fuse element structure 332 includes a laterally-extending the-fuse element base 112 and at least one vertically-extending e-fuse element sidewall 114 extending upwardly from the e-fuse element base 112. As discussed above with respect to FIG. 1, in some examples the vertically-extending e-fuse element sidewall(s) 114 may define a ring shape or a rectangular shape in a cross-section through a horizontal (x-y) plane, and the thickness T₁₁₄ of the (or each) e-fuse element sidewall 114 may be substantially smaller than the thickness T₁₁₂ of the e-fuse element base 112.

In some examples, the e-fuse element layer 330 may comprise NiCr, tin, lead, silver, copper, zinc, aluminum, an alloy of lead and tin, or any other material suitable for e-fuse, for example a material having a low melting temperature, high resistivity, and prone to electromigration. In some examples, the e-fuse element layer 330 may be deposited by Physical Vapor Deposition (PVD) process. The thickness T₃₃₀ of the deposited e-fuse element layer 330 may define the thickness T₁₁₄ of the e-fuse element sidewall 114. As discussed above, the e-fuse element sidewall thickness T₁₁₄ may affect the programming voltage or other performance characteristics of the e-fuse device 100. Thus, the thickness T₃₃₀ of the e-fuse element layer may be selected to provide a desired e-fuse element sidewall thickness T₁₁₄. In some examples, the thickness T₃₃₀ of the e-fuse element layer may be in the range of 100 Å to 1000 Å to provide an e-fuse element sidewall thickness T₁₁₄ in the range of 50 Å to 500 Å.

As shown in FIG. 3F, a shock absorber layer 340 is deposited over the e-fuse element layer 330 and extending down into a cavity 122 defined by the cup-shaped e-fuse element structure 332 in the e-fuse tub opening 116. The shock absorber layer 340 may comprise a dielectric material. In some examples, the shock absorber layer 340 and may comprise a porous dielectric material, for example porous silicon oxide (SiO₂), porous OSG (organo-silicate glass), FSG (Fluorosilicate glass), or a spin-on glass, for example HSQ (Hydrogen Silsesquioxane).

As shown in FIG. 3G, a planarization process (e.g., a CMP process) is performed to remove upper portions of the shock absorber layer 340, upper portions of the e-fuse element layer 330, and the sacrificial thickness T_{SAC} of the dielectric region 302, leaving the dielectric thickness T_{BASE}, also referred to herein as the dielectric region 118. After the planarization process, (a) remaining portions of the via metal 312 in the via openings 212 define the vias 210, (b) a remaining portion of the via metal 312 in the via opening 134 defines the lower e-fuse terminal contact 130 in contact with the lower e-fuse terminal 104, (c) a remaining portion of the cup-shaped e-fuse element structure 332 defines the cup-shaped e-fuse element 110, and (f) a remaining portion of the shock absorber layer 340 defines the shock absorber 120.

As shown in FIG. 3H, the upper metal layer Mₓ₊₁ may be formed over the dielectric region 118, e.g., by a deposition and etch process or a damascene process. The upper metal layer Mₓ₊₁ may include various metal structures including the upper interconnect element 206 connected to the lower interconnect element 204 by via(s) 210, the lower e-fuse terminal contact pad 132, and the upper e-fuse terminal 106. In some examples, the upper metal layer Mₓ₊₁ may comprise interconnect elements formed by deposition of a metal layer (e.g., copper or aluminum), and patterning and etching the metal layer.

Thus, according to the example process discussed, an e-fuse device 100 may be constructed concurrently with interconnect structures (e.g., example interconnect structure 202), and may be constructed without adding any photomask processes to the background IC device fabrication process.

As discussed above, in some examples the e-fuse device 100 may be constructed with the cup-shaped e-fuse element 110 formed below the first metal layer, often referred to as the M1 or Metal-1 layer. For example, FIG. 4 illustrates an example in which the example IC device 200 shown in FIG. 2 is formed between a lower metal layer comprising silicided poly structures (i.e., Mₓ=M₀) and an upper metal layer comprising the Metal-1 or M1 layer (i.e., Mₓ₊₁=M₁). As shown, the lower e-fuse terminal 104 may comprise a silicided polysilicon structure including a polysilicon region 402 having a metal silicide layer region 404 formed thereon, and the lower interconnect element 204 may comprise another silicided polysilicon structure including a polysilicon region 406 having a metal silicide layer region 408 formed thereon. The silicide layer regions 404 and 408 may comprise titanium silicide, cobalt silicide, or nickel silicide, for example.

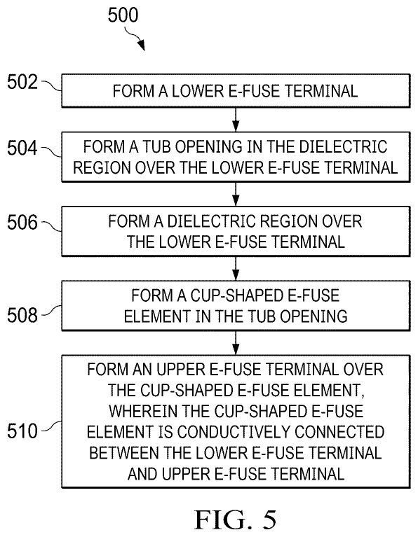

FIG. 5 is a flowchart of an example method 500 for forming an e-fuse device, e.g., the example e-fuse device 100 discussed above. At 502, a lower e-fuse terminal is formed, for example in a lower metal layer Mₓ. At 504, a dielectric region is formed over the lower e-fuse terminal. At 506, a tub opening is formed in the dielectric region over the lower e-fuse terminal, e.g., by etching through the dielectric region. At 508, a cup-shaped e-fuse element in the tub opening. A shock absorber may then be formed in a cavity defined by the cup-shaped e-fuse element, e.g., by depositing a porous dielectric material over the dielectric region and extending down into the cavity defined by the cup-shaped e-fuse element. At 510, an upper e-fuse terminal is formed over the cup-shaped e-fuse element, wherein the cup-shaped e-fuse element is conductively connected between the lower e-fuse terminal and upper e-fuse terminal.

Although example embodiments have been described above, other variations and embodiments may be made from this disclosure without departing from the spirit and scope of these embodiments.

1. An e-fuse device, comprising:
a lower e-fuse terminal;
an upper e-fuse terminal; and
a cup-shaped e-fuse element connected between the lower e-fuse terminal and upper e-fuse terminal, the cup-shaped e-fuse element including an e-fuse element base and an e-fuse element sidewall extending upwardly from the e-fuse element base.

2. The e-fuse device of claim 1, wherein the cup-shaped e-fuse element comprises nichrome (NiCr).

3. The e-fuse device of claim 1, wherein the cup-shaped e-fuse element comprises tin, lead, silver, copper, zinc, aluminum, or an alloy of lead and tin.

4. The e-fuse device of claim 1, comprising a shock absorber formed in a cavity defined by the cup-shaped e-fuse element.

5. The e-fuse device of claim 4, wherein the shock absorber comprises a dielectric material.

6. The e-fuse device of claim 4, wherein the shock absorber comprises a porous dielectric material.

7. The e-fuse device of claim 4, wherein the shock absorber comprises organo-silicate glass (OSG), hydrogen silsesquioxane (HSQ), silicon oxide, or fluorosilicate glass (FSG).

8. The e-fuse device of claim 4, wherein the shock absorber is contained in a chamber defined between the cup-shaped e-fuse element and the upper e-fuse terminal.

9. The e-fuse device of claim 1, comprising:
a lower e-fuse terminal contact pad adjacent the upper e-fuse terminal; and
a lower e-fuse terminal contact adjacent the cup-shaped e-fuse element and defining a conductive connection between the lower e-fuse terminal contact pad and the lower e-fuse terminal.

10. The e-fuse device of claim 9, wherein the lower e-fuse terminal contact pad and the upper e-fuse terminal are formed in the same metal interconnect layer.

11. An integrated circuit (IC) device, comprising:
a lower metal layer;
an upper metal layer;
a via layer between the lower metal layer and upper metal layer;
an e-fuse device including:
a lower e-fuse terminal formed in the lower metal layer;
an upper e-fuse terminal formed in the upper metal layer; and
a cup-shaped e-fuse element formed in the via layer and connected between the lower e-fuse terminal and the upper e-fuse terminal; and
an interconnect structure laterally offset from the e-fuse device, the interconnect structure comprising:
a lower interconnect element formed in the lower metal layer;
an upper interconnect element formed in the upper metal layer; and
at least one via formed in the via layer, the at least one via conductively connected between the lower interconnect element and upper interconnect element.

12. The IC device of claim 11, wherein the e-fuse device comprises a shock absorber formed in a cavity defined by the cup-shaped e-fuse element.

13. The IC device of claim 12, wherein the shock absorber comprises a porous dielectric material.

14. The IC device of claim 11, wherein the e-fuse element is formed from a different metal than the at least one via.

15. The IC device of claim 11, wherein the e-fuse device comprises:
a lower e-fuse terminal contact pad adjacent the upper e-fuse terminal; and
a lower e-fuse terminal contact adjacent the cup-shaped e-fuse element and defining a conductive connection between the lower e-fuse terminal contact pad and the lower e-fuse terminal.

16. A method of forming an e-fuse device, comprising:
forming a lower e-fuse terminal;
forming a dielectric region over the lower e-fuse terminal;
forming a tub opening in the dielectric region over the lower e-fuse terminal;
forming a cup-shaped e-fuse element in the tub opening; and
forming an upper e-fuse terminal over the cup-shaped e-fuse element;
wherein the cup-shaped e-fuse element is conductively connected between the lower e-fuse terminal and upper e-fuse terminal.

17. The method of claim 16, comprising forming a shock absorber in a cavity defined by the cup-shaped e-fuse element.

18. The method of claim 17, wherein forming the shock absorber comprises depositing a porous dielectric material over the dielectric region and extending down into the cavity defined by the cup-shaped e-fuse element.

19. The method of claim 16, comprising.
forming, in the dielectric region, (a) the tub opening over the lower e-fuse terminal and (b) at least one via opening over the lower interconnect element;
depositing a via metal layer over the dielectric region and extending down into the at least one via opening and into the tub opening; and
removing the via metal layer from the tub opening prior to forming the cup-shaped e-fuse element in the tub opening.

20. The method of claim 16, comprising:
forming the lower e-fuse terminal and a lower interconnect element in a lower metal layer;
forming the dielectric region over the lower metal layer;
forming, in the dielectric region, (a) the tub opening over the lower e-fuse terminal and (b) at least one via opening over the lower interconnect element;
depositing a via metal layer over the dielectric region and extending down into the at least one via opening and into the tub opening;
performing an etch to remove the via metal layer from the tub opening;
depositing an e-fuse element layer over the dielectric region and extending down into the tub opening to form a cup-shaped e-fuse element structure in the tub opening;
depositing a shock absorber layer over the e-fuse element layer and extending down into a cavity defined by the cup-shaped e-fuse element structure in the tub opening;
performing a planarization process to remove upper portions of the e-fuse element layer and shock absorber layer, wherein a remaining portion of the e-fuse element layer in the tub opening defines the cup-shaped e-fuse element, and wherein a remaining portion of the shock absorber layer in the tub opening defines a shock absorber; and
forming the upper e-fuse terminal and an upper interconnect element in a lower metal layer, wherein the upper interconnect element is electrically connected to the lower interconnect element by the at least one via.
